(19) United States
(12) Patent Application Publication
(10) Pub. No.: US 2025/0192249 A1
(43) Pub. Date: Jun. 12, 2025

(54) HEATING SAFETY EVALUATOR

(71) Applicant: HONDA MOTOR CO., LTD., Tokyo (JP)

(72) Inventors: Kazuki CHIBA, Saitama (JP); Masahiro OHTA, Saitama (JP)

(21) Appl. No.: 18/966,151

(22) Filed: Dec. 3, 2024

(30) Foreign Application Priority Data
Dec. 6, 2023 (JP) 2023-206476

(51) Int. Cl. H01M 10/42; G01M 99/00

(52) U.S. Cl. CPC H01M 10/4285; G01M 99/002

(57) ABSTRACT

A heating safety evaluator includes a sensor, a heater, a cooler, and a controller. The controller repeatedly performs a prescribed series of control. The series of control includes heating the sample and thereafter, upon detection of self-heat generation by the sensor, bringing the sample into a pseudo-adiabatic state by heating with a periphery heater while making an attempt to cause the self-heat generation to cease by cooling the sample with the cooler. The pseudo-adiabatic state is a state in which a heat balance between the sample cooled with the cooler and periphery of the sample is zero. The heating safety evaluator evaluates a temperature of the sample at which the self-heat generation does not cease during repetition of the series of control, as a critical temperature at which thermal runaway of the sample occurs even by cooling with the cooler.

This application is based on and claims the benefit of priority from Japanese Patent Application No. 2023-206476, filed on 6 Dec. 2023, the content of which is incorporated herein by reference.

### BACKGROUND OF THE INVENTION

### Field of the Invention

The present invention relates to a heating safety evaluator for evaluating the heating safety of a sample.

### Related Art

In recent years, electric vehicles, such as EVs and HEVs, have become widespread. For these electric vehicles, one of the issues is to improve the safety, particularly to improve the safety of batteries.
Patent Document 1: Japanese Unexamined Patent Application, Publication No. 2016-18638

### SUMMARY OF THE INVENTION

Heating safety evaluators, which are used as the devices for evaluating the heating safety of batteries and other articles to be mounted on electric vehicles, may include a heating safety evaluator configured as follows. Specifically, the heating safety evaluator includes a sensor that detects self-heat generation of a sample such as a battery, and a periphery heater configured to be able to heat the periphery of the sample.

The heating safety evaluator heats the sample using the periphery heater. Thereafter, when the sensor detects self-heat generation of the sample, the self-heat generation of the sample is monitored while the sample is controlled to be in a predetermined pseudo-adiabatic state using the periphery heater. The term “pseudo-adiabatic state” used herein means a state in which a heat balance between the sample and its periphery is zero.

The heating safety evaluator described above makes it possible to track temperature change of the sample in the adiabatic state. Therefore, a self-heat generation rate of the sample at each temperature can be evaluated. However, the present inventors paid attention to the following issues.

Specifically, actual batteries are often equipped with some sort of cooling means in a predetermined form at a prescribed place. It is not possible to evaluate critical temperature at which a sample continues to increase in temperature due to self-heat generation even with the presence of the cooling means, that is, the critical temperature at which thermal runaway occurs even with the presence of the cooling means. In addition, when the self-heat generation of the sample is large, the load on the periphery heater at the time of maintaining the pseudo-adiabatic state increases.

Although description has been given with the case where an evaluation target is a battery as an example, similar issues may arise when the evaluation target is other than a battery.

The present invention has been made in view of the above-stated circumstances, and an object of the present invention is to enable evaluation of the critical temperature at which thermal runaway of a sample occurs even with the presence of a cooling means and to reduce the load on a periphery heater.

The present inventors have found that the object can be accomplished by installing a cooler that cools a sample and performing prescribed control, and have thereby completed the present invention. The present invention is a heating safety evaluation device according to aspects (1) to (10) below.

(1) A heating safety evaluator includes:
a sensor configured to detect self-heat generation of a sample;
a periphery heater configured to be able to heat a periphery of the sample;
a cooler configured to be able to cool the sample; and
a controller configured to repeatedly perform a prescribed series of control. The series of control includes heating the sample and thereafter, upon detection of the self-heat generation by the sensor, bringing the sample into a pseudo-adiabatic state by heating with the periphery heater while making an attempt to cause the self-heat generation to cease by cooling the sample with the cooler,
the pseudo-adiabatic state is a state in which a heat balance between the sample cooled with the cooler and the periphery of the sample is zero, and
a temperature of the sample at which the self-heat generation does not cease during repetition of the series of control is evaluated as a critical temperature at which thermal runaway of the sample occurs even with cooling by the cooler.

According to the above feature, when the configuration, such as arrangement and a cooling rate of the cooler, is modeled on the configuration of an actual cooling means, it is possible to evaluate the critical temperature at which thermal runaway of the sample occurs even with the presence of a cooling means. In addition, since the sample is cooled with the cooler, the temperature rise of the sample due to self-heat generation of the sample is suppressed accordingly. Therefore, the load on the periphery heater at the time of maintaining the pseudo-adiabatic state can be reduced accordingly, and the heating safety of a sample having a higher heat generation rate can be evaluated.

Thus, the above feature enables evaluation of the critical temperature at which thermal runaway of the sample occurs even with the presence of a cooling means and also allows reduction of the load on the periphery heater.

(2) The heating safety evaluator according to (1) further includes a heater configured to be able to heat the sample. The series of control includes heating the sample and thereafter, upon detection of the self-heat generation by the sensor, bringing the sample into the pseudo-adiabatic state by heating with the periphery heater while cooling the sample with the cooler and heating the sample with the heater, and the pseudo-adiabatic state is a state in which a heat balance between the sample cooled with the cooler and heated with the heater and the periphery of the sample is zero.

According to the above feature, the heating safety evaluator includes not only the cooler but also the heater, so that the temperature distribution in the periphery of the sample can be more accurately modeled on an actual temperature distribution.

(3) In the heating safety evaluator according to (1) or (2), the cooler includes an element having a heat absorbing surface and a heat generating surface, and cools the sample with the heat absorbing surface.

This feature makes it possible to adjust the heat balance due to the cooler to zero in a system including the sample and the periphery thereof.

(4) In the heating safety evaluator according to any one of (1) to (3), the controller determines that the self-heat generation has ceased when a temperature rise rate of the sample is equal to or less than 0.02° C./min.

The detection limit for the temperature rise rate is generally 0.02° C./min. When the temperature rise rate is equal to or less than the detection limit, the self-heat generation is regarded as having ceased. Thus, the evaluation test can be implemented as accurately as possible.

(5) In the heating safety evaluator according to (3), the cooler includes a cooling Peltier element that cools the sample with the heat absorbing surface, and a cooling circuit that supplies electric power to the cooling Peltier element, and
the controller controls the cooling circuit to control the cooler.

Due to this feature, the rate of cooling by the cooler can be controlled quantitatively by controlling a current flowing to the cooling Peltier element.

(6) In the heating safety evaluator according to (2), the heater includes a heating Peltier element that heats the sample with a heat generating surface, and a heating circuit that supplies electric power to the heating Peltier element, and
the controller controls the heating circuit to control the heater.

Due to this feature, a heating rate by the heater can be controlled quantitatively by controlling a current flowing to the heating Peltier element.

(7) In the heating safety evaluator according to any one of (1) to (6), a plurality of Peltier elements are installed for the sample.

Due to this feature, the temperature and temperature distribution of the sample can be controlled accurately by controlling the plurality of Peltier elements. Therefore, it is possible to simulate an actual state of the sample with more accuracy.

(8) In the heating safety evaluator according to (2), the heater includes a heating Peltier element that heats the sample with a heat generating surface, and a heating circuit that supplies electric power to the heating Peltier element, the cooler includes a cooling Peltier element that cools the sample with the heat absorbing surface, and a cooling circuit that supplies electric power to the cooling Peltier element, a prescribed portion of the sample is heated with the heat generating surface of the heating Peltier element, and another portion of the sample is cooled with the heat absorbing surface of the cooling Peltier element.

Due to this feature, both heating and cooling of the sample can be carried out with the plurality of Peltier elements.

(9) The heating safety evaluator according to any one of (1) to (8) further includes a sample container that stores the sample, and the sample container is hexahedral.

Actual containers for storing batteries or the like are often hexahedral. Therefore, this feature makes it easy to perform tests simulating an actual container.

(10) The heating safety evaluator according to any one of (1) to (8) further includes a sample container that stores the sample, and the sample container is cylindrical.

Actual containers for storing batteries or the like are often cylindrical. Therefore, this feature makes it easy to perform tests simulating an actual container.

As described above, the feature of (1) above enables evaluation of the critical temperature at which thermal runaway of the sample occurs even with the presence of a cooling means and also allows reduction of the load on the periphery heater. Furthermore, the features of (2) to (10) according to (1) above can provide respective additional effects.

### BRIEF DESCRIPTION OF THE DRAWINGS

FIG. 1 is a schematic diagram showing a heating safety evaluator of a first embodiment;

FIG. 2 is a circuit diagram showing a heater and a cooler;

FIG. 3 is a perspective view showing an example of the arrangement of a sample container and Peltier elements;

FIG. 4 is a perspective view showing another example of the arrangement of the sample container and the Peltier elements;

FIG. 5 is a flowchart showing a flow of control by a controller; and

FIG. 6 is a graph showing the relationship between the temperature of a sample and a heat generation rate and the like of the sample.

### DETAILED DESCRIPTION OF THE INVENTION

Hereinafter, embodiments of the present invention are described with reference to the drawings. It should be noted that the present invention is not limited to the following embodiments and appropriate modifications are possible without deviating from the spirit of the present invention.

### First Embodiment

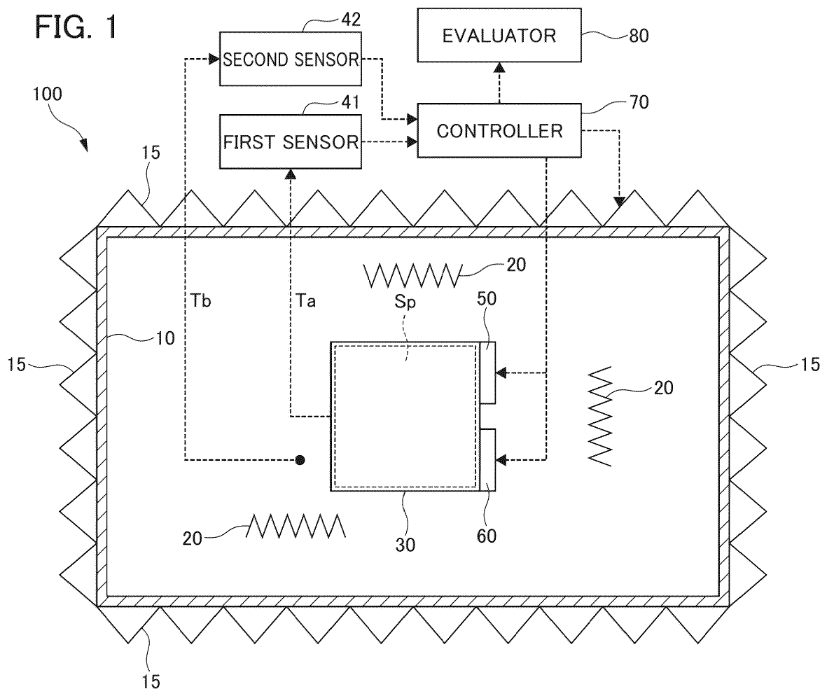

As shown in FIG. 1, the heating safety evaluator 100 of the present embodiment includes a system container 10, a sample container 30, a first sensor 41, a second sensor 42, a periphery heater 20, a heater 50, a cooler 60, a controller 70, and an evaluator 80. Hereafter, the first sensor 41 and the second sensor 42 are simply referred to as “sensors 41 and 42”.

In the present embodiment, a sample Sp is a battery. The sample container 30 stores the sample Sp

The sample Sp is preferably in contact with the sample container 30 from the inside. However, when the sample Sp cannot be in contact, the sample Sp and the sample container 30 are preferably as close as possible. Examples of the case where the sample Sp cannot be in contact may include a case where a battery as the sample Sp includes a protruding terminal, and a portion around the terminal of the sample Sp cannot be in contact with the sample container 30 from the inside. In such a case, a heat transfer material is provided between a portion of the sample Sp, which cannot be in contact with the sample container 30, and the sample container 30. It is preferable that the heat transfer material is sufficiently smaller (e.g. one-twentieth or less) in heat capacity than the sample, and has a thermal conductivity equal to or larger than that of the sample.

The sample container 30 is modeled on the casing of an intelligent power unit (IPU) in which the battery is actually mounted. However, instead of this configuration, a configuration where the content of the battery constitutes the sample Sp and an external casing of the battery itself constitutes the sample container 30 may be adopted to carry out the present embodiment.

The system container 10 stores the sample container 30. The system container 10 is surrounded with an insulating material 15 provided to keep heat in the system container 10. The first sensor 41 detects a surface temperature Ta of the sample container 30 and also detects the temperature of the sample Sp and self-heat generation of the sample Sp based on the surface temperature Ta. The second sensor 42 detects a peripheral temperature Tb of the sample container 30 in the system container 10.

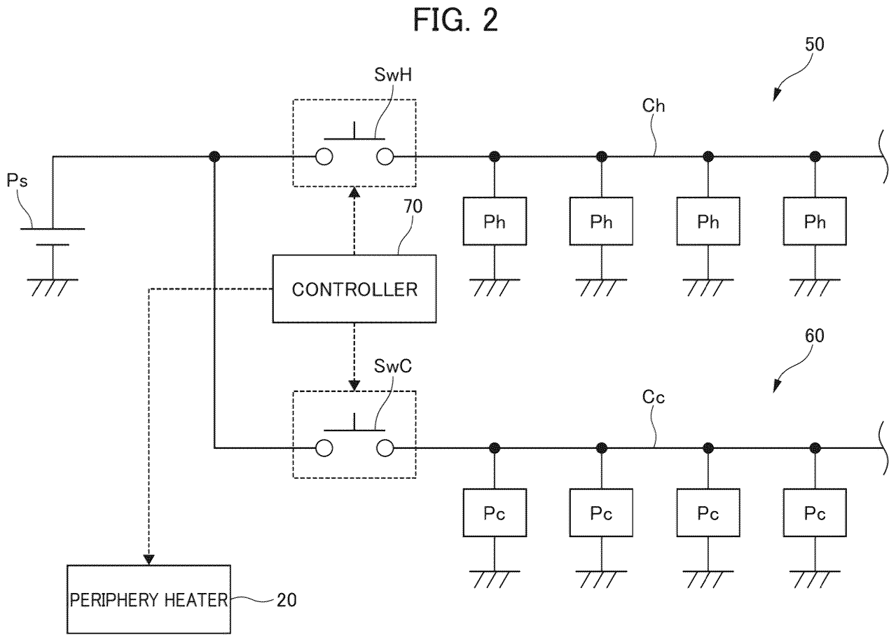

The heater 50 is configured to be able to heat the sample Sp. The cooler 60 is configured to be able to cool the sample Sp. Specifically, the heater 50 heats the sample container 30 to heat the sample Sp. The cooler 60 cools the sample container 30 to cool the sample Sp. More specifically, as shown in FIG. 2, the heater 50 includes a plurality of heating Peltier elements Ph and a heating circuit Ch. The cooler 60 includes a plurality of cooling Peltier elements Pc and a cooling circuit Cc.

Both the heating Peltier elements Ph and the cooling Peltier elements Pc are Peltier elements each including a heat generating surface that generates heat when an electric current flows, and a heat absorbing surface that absorbs heat when an electric current flows. The heat generating surface of each of the heating Peltier elements Ph is in contact with the sample container 30. The heat absorbing surface of each of the cooling Peltier elements Pc is in contact with on the sample container 30. Hereafter, the heating Peltier elements Ph and the cooling Peltier elements Pc are referred to as “Peltier elements Ph and Pc”.

The heating circuit Ch, which supplies electric power to each of the heating Peltier elements Ph, includes a heating switch SwH. Through the heating switch SwH, a power supply Ps is electrically connected to each of the heating Peltier elements Ph. Therefore, when the heating switch SwH is turned on, each of the heating Peltier elements Ph heats the sample container 30 with the heat generating surface. As a result, the sample Sp is heated. On the other hand, when the heating switch SwH is turned off, the heating is stopped.

The cooling circuit Cc, which supplies electric power to each of the cooling Peltier elements Pc, includes a cooling switch SwC. Through the cooling switch SwC, the power supply Ps is electrically connected to each of the cooling Peltier elements Pc. Therefore, when the cooling switch SwC is turned on, each of the cooling Peltier elements Pc cools the sample container 30 with the heat absorbing surface. As a result, the sample Sp is cooled. On the other hand, when the cooling switch SwC is turned off, the cooling is stopped.

The heating circuit Ch and the cooling circuit Cc are further configured such that the output of the Peltier elements Ph and Pc can be controlled quantitatively. Specific examples thereof may include a mode in which the heating switch SwH and the cooling switch SwC are semiconductor switches and are under duty control. There may also be a mode in which a semiconductor switch is provided for each of the Peltier elements Ph and Pc, and each semiconductor switch is under duty control so that the output of each of the Peltier elements Ph and Pc is quantitatively controlled.

The periphery heater 20 shown in FIG. 1 is configured to be able to heat the periphery of the sample container 30 in the system container 10. Under prescribed conditions, the periphery heater 20 heats the periphery of the sample container 30 to attain a pseudo-adiabatic state. Note that the term “pseudo-adiabatic state” used here refers to a state in which a heat balance between the sample Sp heated with the heater 50 and cooled with the cooler 60 and the periphery of the sample Sp is zero. In the pseudo-adiabatic state, the surface temperature Ta of the sample container 30 detected by the first sensor 41 and the peripheral temperature Tb of the sample container 30 detected by the second sensor 42 are kept roughly the same.

The controller 70 controls the periphery heater 20, the heater 50, and the cooler 60 based on information from the sensors 41 and 42. In other words, the controller 70 controls the heater 50 and the cooler 60 as shown in FIG. 2, and also controls the periphery heater 20. The control by the controller 70 is described later in detail.

The evaluator 80 shown in FIG. 1 evaluates a critical temperature Tnr at which thermal runaway of the sample Sp occurs, based on change in temperature of the sample Sp. Note that “Tnr” here stands for “Temperature of No Return”. The evaluation by the evaluator 80 is described later in detail.

The controller 70 and the evaluator 80 may be configured, for example, by the same computer or by separate computers.

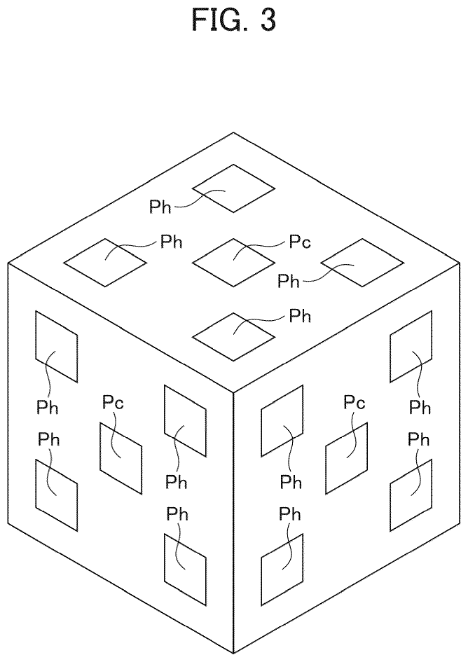

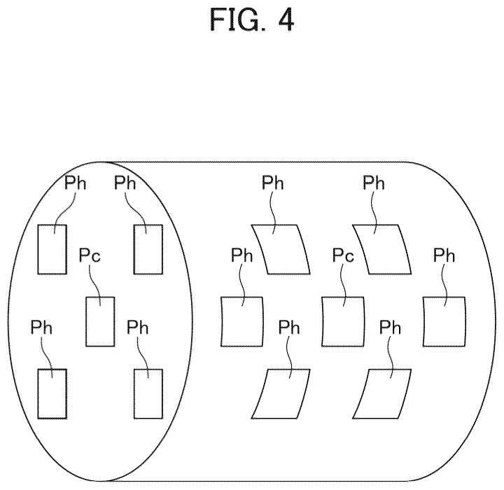

The sample container 30 shown in FIG. 1 may be, for example, hexahedral as shown in FIG. 3 or may be cylindrical as shown in FIG. 4. Specifically, as described above, the shape of the sample container 30 may be modeled on the shape of the casing of an actual IPU as appropriate.

As shown in FIGS. 3 and 4, the plurality of Peltier elements Ph and Pc are installed on the sample container 30. The arrangement and the cooling rate of each of the cooling Peltier elements Pc may be modeled on the arrangement and the cooling rate of each of cooling means installed on the casing of an actual IPU. The arrangement and the heating rate of each of the heating Peltier elements Ph may be modeled on the arrangement and the heating rate of each of heating sources installed on the periphery of the casing of an actual IPU.

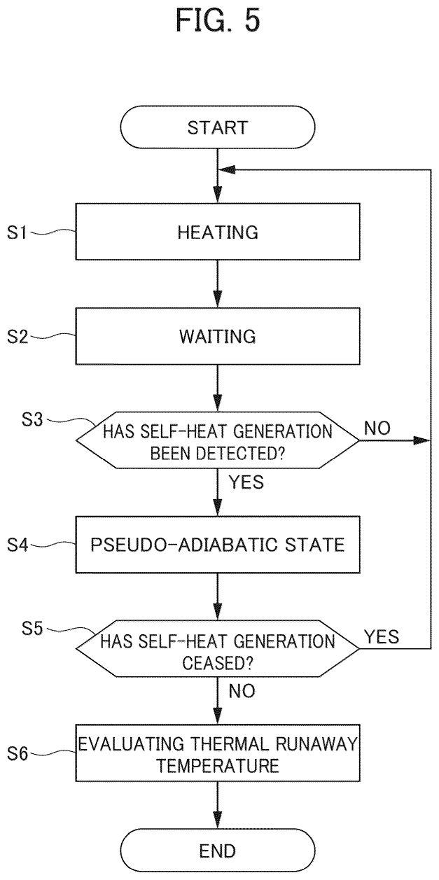

Next, with reference to the flowchart of FIG. 5, control by the controller 70 and evaluation by the evaluator 80 are described in detail. A character S prefixed to numerals below stands for “step”. S1 to S5 are performed by the controller 70, and S6 is performed by the evaluator 80. The control in S1 to S5 may be read as “a series of control”. The series of control is performed while the sample container 30 is heated with the heater 50 and the sample container 30 is cooled with the cooler 60.

The controller 70 first heats the periphery of the sample container 30 using the periphery heater 20. In next S2, the controller 70 waits for a prescribed time. This is to wait for the heat in the periphery of the sample container 30 to be transferred to the sample container 30 and the sample Sp.

In next S3, the controller 70 determines whether or not self-heat generation of the sample Sp has been detected by the first sensor 41. When negative determination is made, that is, the self-heat generation has not been detected, the process returns to S1 and repeats S1 to S3. On the other hand, when positive determination is made, that is, the self-heat generation has been detected, the process proceeds to S4.

In step S4, the periphery of the sample container 30 is heated using the periphery heater 20 so as to control the sample Sp in a pseudo-adiabatic state. Specifically, a heat balance between the sample Sp heated with the heater 50 and cooled with the cooler 60 and the periphery of the sample Sp is controlled to be zero. Then, the sample Sp is monitored for a while.

In next S5, the controller 70 determines whether or not the self-heat generation of the sample Sp has ceased. Specifically, for example, in S5, the controller 70 determines whether or not the self-heat generation of the sample SP has ceased before a predetermined time elapses or before the temperature of the sample SP rises by a predetermined temperature.

It should be noted that the term “ceasing” of the self-heat generation herein refers to suppression of the temperature rise of the sample Sp caused by self-heat generation. Specifically, in the present embodiment, the detection limit of the temperature rise rate by the first sensor 41 is 0.02° C./min. Therefore, when the temperature rise rate of the sample Sp is equal to or less than 0.02° C./min, the controller 70 determines that the self-heat generation has ceased.

When positive determination is made in S5, that is, when the self-heat generation has ceased, the process returns to S1 and repeats S1 to S5. On the other hand, when negative determination is made in S5, that is, the self-heat generation has not ceased, the process proceeds to S6.

In S6, the evaluator 80 evaluates the temperature of the sample SP at the time when self-heat generation is detected in the last S3, as the critical temperature Tnr at which the thermal runaway of the sample Sp occurs even with cooling by the cooler 60.

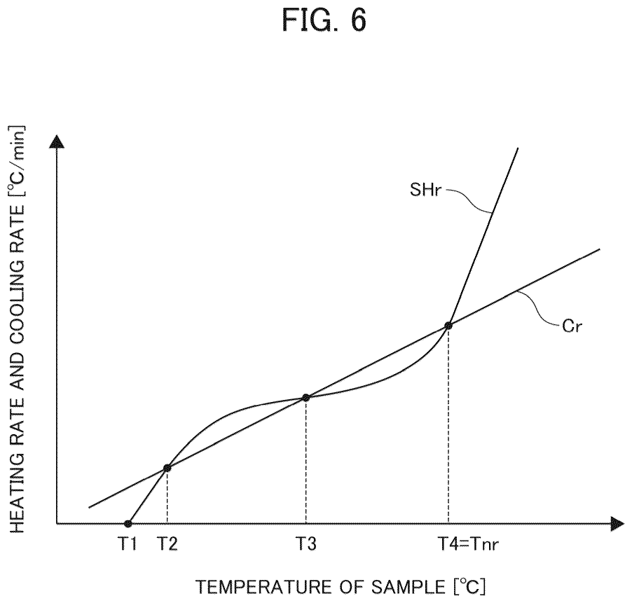

Next, the operation according to the above flow will be described with reference to FIG. 6. It should be noted that a vertical axis in FIG. 6 indicates the heat generation rate and the cooling rate expressed logarithmically. The lower limit of the vertical axis in FIG. 6 indicates 0.02° C./min. Hereinafter, a predetermined temperature is referred to as “first temperature T1”, and predetermined temperatures that are each gradually higher than the first temperature T1 are referred to as “second temperature T2”, “third temperature T3”, and “fourth temperature T4”. A total cooling rate of the sample SP by the heater 50 and the cooler 60 is referred to as “cooling rate Cr” below. In other words, the cooling rate Cr is obtained by offsetting heating by the heater 50.

Here, description is given by taking as an example the case where the self-heat generation rate SHr and the cooling rate Cr of the sample Sp have the following relationship. The sample Sp starts self-heat generation at the first temperature T1. In a period in which the temperature of the sample Sp is between the first temperature T1 and the second temperature T2, the self-heat generation rate SHr is less than the cooling rate Cr. In a period in which the temperature of the sample Sp is between the second temperature T2 and the third temperature T3, the self-heat generation rate SHr is greater than the cooling rate Cr. In a period in which the temperature of the sample Sp is between the third temperature T3 and the fourth temperature T4, the self-heat generation rate SHr becomes again less than the cooling rate Cr. When the temperature of the sample Sp becomes equal to or higher than the fourth temperature T4, the self-heat generation rate SHr becomes greater than the cooling rate Cr again. This relationship between the rates SHr and Cr is maintained in a period in which the temperature of the sample Sp is equal to or higher than the fourth temperature T4.

First, when the temperature of the sample Sp is less than the first temperature T1, negative determination is made in S3, that is, self-heat generation is not detected in S3 after steps S1 and S2 shown in FIG. 5. As a result, the steps S1 to S3 are repeated. The temperature of the sample Sp indicated on the horizontal axis in FIG. 6 rises to the first temperature T1 or higher by heating in S1 during the repetition of S1 to S3. Thus, the sample SP starts self-heat generation. In this case, however, the self-heat generation is not detected since the self-heat generation rate SHr is smaller than the cooling rate Cr. Therefore, S1 to S3 are repeated.

The temperature of the sample Sp indicated on the horizontal axis in FIG. 6 rises to the second temperature T2 or higher by heating in S1 during the repetition of S1 to S3. As a result, the self-heat generation rate SHr becomes greater than the cooling rate Cr, and therefore the self-heat generation is detected. Consequently, the process proceeds to S4 shown in FIG. 5, and the pseudo-adiabatic state is attained. The self-heat generation in the pseudo-adiabatic state causes the temperature of the sample SP to rise up to the third temperature T3 or higher. At this point in time, the self-heat generation rate SHr becomes less than the cooling rate Cr again, and therefore the self-heat generation of the sample Sp is no longer detected. In other words, the self-heat generation of the sample Sp ceases, and positive determination is made in S5 shown in FIG. 5. Consequently, the process returns to S1.

Thereafter, S1 to S3 are repeated since the self-heat generation rate SHr is less than the cooling rate Cr. The temperature of the sample Sp indicated on the horizontal axis in FIG. 6 rises to the fourth temperature T4 or higher by heating in S1 during the repetition of S1 to S3. As a result, the self-heat generation rate SHr becomes greater than the cooling rate Cr again, and therefore the self-heat generation is detected. Consequently, the process proceeds to S4 shown in FIG. 5, and the pseudo-adiabatic state is attained.

Thereafter, this relationship between the rates SHr and Cr, in which the self-heat generation rate SHr is greater than the cooling rate Cr, is maintained as shown in FIG. 6. Therefore, the self-heat generation of the sample SP continues to be detected and does not cease no matter much time elapses. As a result, negative determination is made in S5 in FIG. 5, and the process proceeds to S6.

In S6, the temperature of the sample SP at the time when self-heat generation is detected in the last S3, that is, the temperature equal to or slightly higher than the fourth temperature T4 shown in FIG. 6, is evaluated as the critical temperature Tnr at which the thermal runaway of the sample Sp occurs even with cooling performed by the cooler 60. The result of the evaluation, that is, the critical temperature Tnr, is output by being displayed on a display unit, such as a display screen, for example.

In a case where the cooling rate Cr is set to be higher in a sample Sp that is the same as the sample Sp in FIG. 6, the final intersection point between the cooling rate Cr and the self-heat generation rate SHr shifts to the right, that is, T4 shifts to the right, so that the critical temperature Tnr at which thermal runaway occurs rises. In a case where the cooling rate Cr is set to be lower in a sample SP that is the same the sample Sp as in FIG. 6, the final intersection point between the cooling rate Cr and the self-heat generation rate SHr shifts to the left, that is, T4 shifts to the left, so that the critical temperature Tnr at which thermal runaway occurs falls.

The configuration and effects of the present embodiment are summarized below.

As shown in FIG. 5, the controller 70 repeatedly performs a prescribed series of control (S1 to S5). In the series of control, when the self-heat generation of the sample Sp is detected in S3, the sample Sp is controlled to be in the pseudo-adiabatic state while an attempt to cause the self-heat generation to cease is made by cooling the sample Sp with the cooler 60 in S4, and the sample Sp is monitored. The evaluator 80 evaluates the temperature of the sample Sp at which the self-heat generation does not cease, during repetition of the series of control (S1 to S5), as a critical temperature Tnr at which thermal runaway of the sample Sp occurs even with cooling performed by the cooler 60.

Accordingly, it is possible to evaluate the critical temperature Tnr at which thermal runaway of the sample Sp occurs even with the presence of a cooling means, by modeling the configuration, such as arrangement and the cooling rate of the cooler 60 shown in FIG. 1, on the configuration of an actual cooling means.

The evaluation result can be fed back to the design of the IPU. Specifically, for example, in the case of opening an open valve of a battery cell to lower the temperature of the battery cell with vaporization heat of an electrolyte, a degree Celsius to which the temperature of the battery cell needs to be lowered becomes clear.

Moreover, since the sample Sp is cooled with the cooler 60, the temperature rise of the sample Sp due to self-heat generation of the sample Sp is suppressed accordingly. Therefore, the load on the periphery heater 20 at the time of maintaining the pseudo-adiabatic state can be reduced accordingly.

As shown in FIG. 1, the heating safety evaluator 100 includes not only the cooler 60 but also the heater 50. As a result, the temperature distribution in the periphery of the sample Sp can be more accurately modeled on actual temperature distribution.

As shown in FIG. 2, the cooler 60 includes the cooling Peltier elements Pc as elements each having a heat absorbing surface and a heat generating surface. The sample SP is cooled with the heat absorbing surfaces of the cooling Peltier elements Pc. Therefore, the heat balance by the cooler 60 in the system container 10 shown in FIG. 1 can be set to zero.

The detection limit of the temperature rise rate by the first sensor 41 shown in FIG. 1 is 0.02° C./min. When the temperature rise rate is equal to or less than the detection limit, the self-heat generation is regarded as having ceased. Thus, the evaluation test can be implemented as accurately as possible.

As shown in FIG. 2, the cooler 60 includes cooling Peltier elements that cool the sample Sp with the heat absorbing surfaces, and the cooling circuit Cc that supplies electric power to the cooling Peltier elements. The controller 70 controls the cooling circuit Cc to control the cooler 60. Therefore, the cooling rate Cr by the cooler 60 can be controlled quantitatively.

As shown in FIG. 2, the heater 50 includes heating Peltier elements Ph that heat the sample Sp with the heat generating surfaces, and the heating circuit Ch that supplies electric power to the heating Peltier elements Ph. The controller 70 controls the heating circuit Ch to control the heater 50. Therefore, the heating rate by the heater 50 can be controlled quantitatively.

As shown in FIGS. 3 and 4, the plurality of Peltier elements Ph and Pc are installed for the sample Sp. When the plurality of such Peltier elements Ph and Pc are controlled, the temperature and temperature distribution of the sample Sp can be controlled accurately. Therefore, it is possible to simulate an actual state with more accuracy.

As shown in FIGS. 3 and 4, prescribed portions of the sample Sp are heated with the heat generating surfaces of the heating Peltier elements Ph. Other portions of the sample Sp are cooled with the heat absorbing surfaces of the cooling Peltier elements Pc. Thus, both heating and cooling of the sample Sp can be carried out with the plurality of Peltier elements Ph and Pc.

As shown in FIG. 3, when the sample container 30 is formed to be hexahedral, it is easy to perform tests simulating, for example, the casing of a hexahedral IPU or the like. As shown in FIG. 4, when the sample container 30 is formed to be cylindrical, it is also easy to perform tests simulating, for example, the casing of a cylindrical IPU or the like.

### Other Embodiments

The embodiment described above can be modified as described below. The cooler 60 shown in FIG. 2 may be used to cool the sample Sp by means other than the Peltier elements, such as an air cooler or a water cooler. The heater 50 may heat the sample Sp by means other than the Peltier elements, such as various kinds of heater elements. The heater 50 may be omitted in a case where the temperature distribution of the sample Sp can be modeled on an actual temperature distribution with sufficient accuracy even without the heater 50 shown in FIG. 1.

### EXPLANATION OF REFERENCE NUMERALS

10: System container
20: Periphery heater
30: Sample container
41: First sensor
42: Second sensor
50: Heater
60: Cooler
70: Controller
80: Evaluator
100: Heating safety evaluator
Ta: Surface temperature of sample container
Tb: Peripheral temperature of sample container
Ch: Heating circuit
Cc: Cooling circuit
Ph: Heating Peltier element (Peltier element)
Pc: Cooling Peltier element (Peltier element)
Sp: Sample
SHr: Self-heat generation rate of sample
Cr: Cooling rate of sample
Tnr: Critical temperature at which thermal runaway of sample occurs

What is claimed is:

1. A heating safety evaluator, comprising:
a sensor configured to detect self-heat generation of a sample;
a periphery heater configured to be able to heat a periphery of the sample;
a cooler configured to be able to cool the sample; and
a controller configured to repeatedly perform a prescribed series of control, wherein
the series of control includes heating the sample, and thereafter, upon detection of the self-heat generation by the sensor, bringing the sample into a pseudo-adiabatic state by heating with the periphery heater while making an attempt to cause the self-heat generation to cease by cooling the sample with the cooler,
the pseudo-adiabatic state is a state in which a heat balance between the sample cooled with the cooler and the periphery of the sample is zero, and
a temperature of the sample at which the self-heat generation does not cease during repetition of the series of control is evaluated as a critical temperature at which thermal runaway of the sample occurs even with cooling by the cooler.

2. The heating safety evaluator according to claim 1, further comprising:
a heater configured to be able to heat the sample, wherein
the series of control includes heating the sample and thereafter, upon detection of the self-heat generation by the sensor, bringing the sample into the pseudo-adiabatic state by heating with the periphery heater while cooling the sample with the cooler and heating the sample with the heater, and
the pseudo-adiabatic state is a state in which a heat balance between the sample cooled with the cooler and heated with the heater and the periphery of the sample is zero.

3. The heating safety evaluator according to claim 1, wherein
the cooler comprises an element having a heat absorbing surface and a heat generating surface, and cools the sample with the heat absorbing surface.

4. The heating safety evaluator according to claim 1, wherein
the controller determines that the self-heat generation has ceased when a temperature rise rate of the sample is equal to or less than 0.02° C./min.

5. The heating safety evaluator according to claim 3, wherein
the cooler comprises a cooling Peltier element that cools the sample with the heat absorbing surface, and a cooling circuit that supplies electric power to the cooling Peltier element, and
the controller controls the cooling circuit to control the cooler.

6. The heating safety evaluator according to claim 2, wherein
the heater comprises a heating Peltier element that heats the sample with a heat generating surface, and a heating circuit that supplies electric power to the heating Peltier element, and
the controller controls the heating circuit to control the heater.

7. The heating safety evaluator according to claim 1, wherein
a plurality of Peltier elements are installed for the sample.

8. The heating safety evaluator according to claim 2, wherein
the heater comprises a heating Peltier element that heats the sample with a heat generating surface, and a heating circuit that supplies electric power to the heating Peltier element,
the cooler comprises a cooling Peltier element that cools the sample with a heat absorbing surface, and a cooling circuit that supplies electric power to the cooling Peltier element,
a prescribed portion of the sample is heated with the heat generating surface of the heating Peltier element, and
another portion of the sample is cooled with the heat absorbing surface of the cooling Peltier element.

9. The heating safety evaluator according to claim 1, further comprising:
a sample container that stores the sample, wherein
the sample container is hexahedral.

10. The heating safety evaluator according to claim 1, further comprising:
a sample container that stores the sample, wherein
the sample container is cylindrical.
